(19) United States
(12) Patent Application Publication
(10) Pub. No.: US 2021/0036167 A1
(43) Pub. Date: Feb. 4, 2021

(54) MERGED PiN SCHOTTKY (MPS) DIODE WITH PLASMA SPREADING LAYER AND MANUFACTURING METHOD THEREOF

(71) Applicants: Xiaotian Yu, LOS ANGELES, CA (US); Zheng Zuo, LOS ANGELES, CA (US); Ruigang Li, LOS ANGELES, CA (US)

(72) Inventors: Xiaotian Yu, LOS ANGELES, CA (US); Zheng Zuo, LOS ANGELES, CA (US); Ruigang Li, LOS ANGELES, CA (US)

(73) Assignee: AZ Power, Inc, CULVER CITY, CA (US)

(21) Appl. No.: 16/945,865

(22) Filed: Aug. 1, 2020

Related U.S. Application Data
(60) Provisional application No. 62/881,537, filed on Aug. 1, 2019.

(51) Int. Cl. H01L 29/872; H01L 29/868; H01L 29/66

(52) U.S. Cl. CPC H01L 29/872; H01L 29/66143; H01L 29/868

(57) ABSTRACT

A method for manufacturing a merged PiN Schottky (MPS) diode may include steps of providing a substrate having a first conductivity type; forming an epitaxial layer with the first conductivity type on top of the substrate; forming a plurality of regions with a second conductivity type under a top surface of the epitaxial layer; forming a plasma spreading layer; depositing and patterning a first Ohmic contact metal on the regions with the second conductivity type; depositing a Schottky contact metal on top of the entire epitaxial layer; and forming a second Ohmic contact metal on a backside of the substrate. In another embodiment, the step of forming a plurality of regions with a second conductivity type may include steps of depositing and patterning a mask layer on the epitaxial layer, implanting P-type dopant into the epitaxial layer, and removing the mask layer.

### CROSS-REFERENCE TO RELATED APPLICATIONS

This application claims priority under 35 U.S.C. § 119 (e) to U.S. Provisional Patent Application Ser. No. 62/881,537, filed on Aug. 1, 2019, the entire contents of which are hereby incorporated by reference.

### FIELD OF THE INVENTION

The present invention relates to a power diode structure, and more particularly to a merged PiN junction Schottky (MPS) diode with enhanced reliability under a surge current.

### BACKGROUND OF THE INVENTION

Power devices include power diodes and power switching transistors. Power diodes have two modes of operation in circuit applications, which are conduction mode and blocking mode. For the conduction mode, in addition to nominal current conditions, there is an occasional surge current condition. Under the abnormal conditions with surge current, the diode may have instant energy overshoot and chip temperature rise, resulting in device failure.

Power devices are expected to endure high current stresses under surges caused by circuit failure or lightning. Usually a great amount of energy, caused by high current multiplied by high voltage drop, flows into the device in quite a short time, leading to rapidly raised temperature and possibly a device failure. Surge capability is a key performance index which describes the robustness of power devices under extreme operating conditions. Devices with preeminent surge capability can dissipate such energy efficiently without a failure, thus offering a higher safety margin to the power system.

Silicon carbide semiconductor has two times larger bandgap compared with Silicon semiconductor. With a higher critical electric field, higher thermal conductivity, lower intrinsic carrier concentration, and higher saturation drift velocity, silicon carbide semiconductor has become an ideal candidate for high voltage, high temperature and high-power devices.

There are two technical routes for commercial devices based on silicon carbide power diodes, namely junction barrier Schottky (JBS) diode structure and merged PiN Schottky (MPS) diode structure.

For silicon carbide (SiC) materials, the Junction Barrier Schottky (JBS) diode is widely used. Armed with excellent characteristics of SiC material and characterized by alternatively arranged small P+ regions in N− drift layer, it has received large attention for its low forward voltage drop and low reverse leakage current. Merged PiN Schottky (MPS) diode was proposed based on the JBS diode structure, with merged large P+ regions into the active region. PN junctions formed by these large P+ regions will turn on under high current flows. Large amount of minority carriers will be injected into the drift layer, providing a lower resistivity and a higher current conduction capability. Thus, it offers higher surge capability compared to traditional JBS diode, as well as preserving a low forward voltage drop and reverse leakage current at the same time.

### SUMMARY OF THE INVENTION

In one aspect, a merged PiN Schottky (MPS) diode may include a silicon carbide substrate having a first conductivity type, an epitaxial layer with the first conductivity type formed on the substrate, In one embodiment, the doping concentration in the epitaxial layer is lower than that in the substrate. The merged PiN Schottky (MPS) diode may further include a plurality of regions having a second conductivity type different from the first conductivity type, and formed under a top surface of the epitaxial layer.

A first Ohmic contact metal is formed on top of each of the regions of the second conductivity type, and a Schottky contact metal is placed on top of the entire epitaxial layer to form a Schottky junction. A second Ohmic contact is formed by a cathode electrode on the back side of the substrate.

In one embodiment, the first conductivity is N type, and the second conductivity type is P type. It is noted that in the merged PiN Schottky (MPS) diode structure, a PN junction can be formed by a P+ region, and a N-type drift region can be turned on under surge current condition, forming a parallel operation mode between the PN junction and the Schottky junction 16, providing device with better surge current capability.

In another embodiment, a merged PiN Schottky (MPS) diode structure with hexagonal cells and P+ rings along with a plasma spreading layer, which has three P+ type diagonal lines for each cell, and forms 60 degrees with each other. It is noted that the plasma spreading layer design can connect all the P+ hexagons and outer P+ rings. During a surge current shock, the PN junction formed by the large P+ hexagon and N-type drift layer is first turned on, then the bipolar effect takes place and the electron-holes are created. With the help of the plasma spreading layer, the electron-hole plasma can be dispersed to the whole area of the device. As a result, the high surge current and dissipated energy can be evenly distributed within the device, effectively preventing the device damage caused by localized heating, and thus improving the surge current capability of the device.

It is noted that there are various kinds of arrangements for the plasma spreading layer design. For example, rotating the plasma spreading layer by 30 degrees based on the design stated above, another layout design with 60-degree cross network can be obtained, which also has three P+ type diagonal lines for each cell, and forms 60 degrees with each other. Likewise, the plasma spreading layer design can connect all the P+ hexagons and outer P+ rings, and during a surge current shock, the PN junction formed by the large P+ hexagon and N-type drift layer is first turned on, then the bipolar effect takes place and the electron-holes are created. With the help of the plasma spreading layer, the electron-hole plasma can be dispersed to the whole area of the device. As a result, the high surge current and dissipated energy can be evenly distributed within the device, effectively preventing the device damage caused by localized heating, and thus improving the surge current capability of the device.

In still another embodiment, even if the number of the narrow P+ regions (i.e. the hexagonal rings) are reduced, as long as the device has the plasma spreading layer having three P+ type diagonal lines for each cell, the current and the generated heat during the surge current shock can be uniformly diffused over the whole device area.

Likewise, rotating the plasma spreading layer by 30 degrees based on the design with reduced narrow P+ regions, another layout design with 60-degree cross network can be obtained, which also has three P+ type diagonal lines for each cell, and forms 60 degrees with each other.

In addition to the cross-network structure formed by the straight lines as stated above, the plasma spreading layer can also be formed in other shapes. For example, an interconnected hexagonal plasma spreading layer can also uniformly spread current and the generated heat to the whole device area, effectively preventing device damage caused by localized heating, improving the surge current capability.

In another aspect, a method for manufacturing a merged PiN Schottky (MPS) diode may include steps of providing a substrate having a first conductivity type; forming an epitaxial layer with the first conductivity type on top of the substrate; forming a plurality of regions with a second conductivity type under a top surface of the epitaxial layer; forming a plasma spreading layer in each region; depositing and patterning an Ohmic contact metal on the regions with the second conductivity type; depositing a Schottky contact metal on top of the entire epitaxial layer; and forming an Ohmic contact metal on a backside of the substrate.

In one embodiment, the epitaxial layer is made of N-type silicon carbide. In another embodiment, the step of forming a plurality of regions with a second conductivity type under a top surface of the epitaxial layer may include steps of depositing and patterning a mask layer on the epitaxial layer, implanting P-type dopant into the epitaxial layer, and removing the mask layer. It is noted that the dopant can be aluminum or boron.

In a further embodiment, the step of depositing and patterning an Ohmic contact metal on the regions may include a step of annealing the Ohmic metal to enable the metal to be in direct contact with the epitaxial layer. In still a further embodiment, the step of depositing a Schottky contact metal on top of the entire epitaxial layer may include a step of conducting a low temperature annealing of the Schottky contact metal.

### BRIEF DESCRIPTION OF THE DRAWINGS

FIG. 1 is a cross-section view of the merged PiN Schottky (MPS) diode in the present invention.

FIG. 2 is a schematic view of a layout design of a merged PiN Schottky (MPS) diode with hexagonal cells and P+ ring design.

FIG. 3 is a schematic view of a merged PiN Schottky (MPS) diode with a 60-degree cross network plasma spreading layer.

FIG. 4 is a partial enlarged sectional view of the merged PiN Schottky (MPS) diode with a 60-degree cross network plasma spreading layer in FIG. 3.

FIG. 5 is a schematic view of a merged PiN Schottky (MPS) diode with a 60-degree cross network plasma spreading layer that is rotated by 30 degrees from FIG. 3.

FIG. 6 is a partial enlarged sectional view of the merged PiN Schottky (MPS) diode with a 60-degree cross network plasma spreading layer in FIG. 5.

FIG. 7 is a partial enlarged sectional view of a merged PiN Schottky (MPS) diode with a plasma spreading layer and reduced narrow P+ regions.

FIG. 8 is a partial enlarged sectional view of the merged PiN Schottky (MPS) diode having reduced narrow P+ regions and a plasma spreading layer rotated by 30 degrees from FIG. 7.

FIG. 9 is a partial enlarged sectional view of a merged PiN Schottky (MPS) diode with an interconnected hexagonal plasma spreading layer.

FIG. 10 shows the experiment results of the plasma spreading layer enhancing the surge current capability of the merged PiN junction Schottky (MPS) diode.

FIG. 11. shows the experiment results of the plasma spreading layer enhancing the maximum withstanding energy of the merged PiN junction Schottky (MPS) diode.

FIGS. 12A to 12G illustrate flow diagrams of the method for manufacturing a merged PiN Schottky (MPS) diode in the present invention.

FIG. 13 is a block diagram illustrating the method for manufacturing a merged PiN Schottky (MPS) diode in the present invention.

### DETAILED DESCRIPTION OF THE INVENTION

The detailed description set forth below is intended as a description of the presently exemplary device provided in accordance with aspects of the present invention and is not intended to represent the only forms in which the present invention may be prepared or utilized. It is to be understood, rather, that the same or equivalent functions and components may be accomplished by different embodiments that are also intended to be encompassed within the spirit and scope of the invention.

Unless defined otherwise, all technical and scientific terms used herein have the same meaning as commonly understood to one of ordinary skill in the art to which this invention belongs. Although any methods, devices and materials similar or equivalent to those described can be used in the practice or testing of the invention, the exemplary methods, devices and materials are now described.

All publications mentioned are incorporated by reference for the purpose of describing and disclosing, for example, the designs and methodologies that are described in the publications that might be used in connection with the presently described invention. The publications listed or discussed above, below and throughout the text are provided solely for their disclosure prior to the filing date of the present application. Nothing herein is to be construed as an admission that the inventors are not entitled to antedate such disclosure by virtue of prior invention.

As used in the description herein and throughout the claims that follow, the meaning of “a”, “an”, and “the” includes reference to the plural unless the context clearly dictates otherwise. Also, as used in the description herein and throughout the claims that follow, the terms “comprise or comprising”, “include or including”, “have or having”, “contain or containing” and the like are to be understood to be open-ended, i.e., to mean including but not limited to. As used in the description herein and throughout the claims that follow, the meaning of “in” includes “in” and “on” unless the context clearly dictates otherwise.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein, the term “and/or” includes any and all combinations of one or more of the associated listed items.

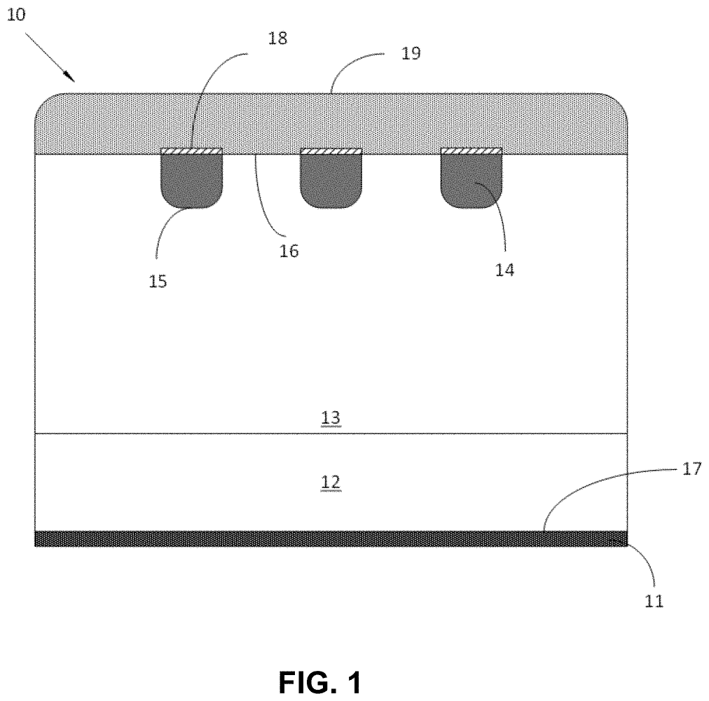

In one aspect as shown in FIG. 1, a merged PiN Schottky (MPS) diode 10 may include a silicon carbide substrate 12 having a first conductivity type, an epitaxial layer 13 with the first conductivity type formed on the substrate 12, In one embodiment, the doping concentration in the epitaxial layer 13 is lower than that in the substrate 12. The merged PiN Schottky (MPS) diode 10 may further include a plurality of regions 14 having a second conductivity type different from the first conductivity type, and formed under a top surface of the epitaxial layer 13.

A first Ohmic contact metal 18 is formed on top of each of the regions of the second conductivity type, and a Schottky contact metal 19 is placed on top of the entire epitaxial layer 13 to form a Schottky junction 16. A second Ohmic contact 17 is formed by a cathode electrode 11 on the back side of the substrate 12.

In one embodiment, the first conductivity is N type, and the second conductivity type is P type. It is noted that in the merged PiN Schottky (MPS) diode structure, a PN junction can be formed by a P+ region 14, and a N-type drift region 15 can be turned on under surge current condition, forming a parallel operation mode between the PN junction and the Schottky junction 16, providing device with better surge current capability.

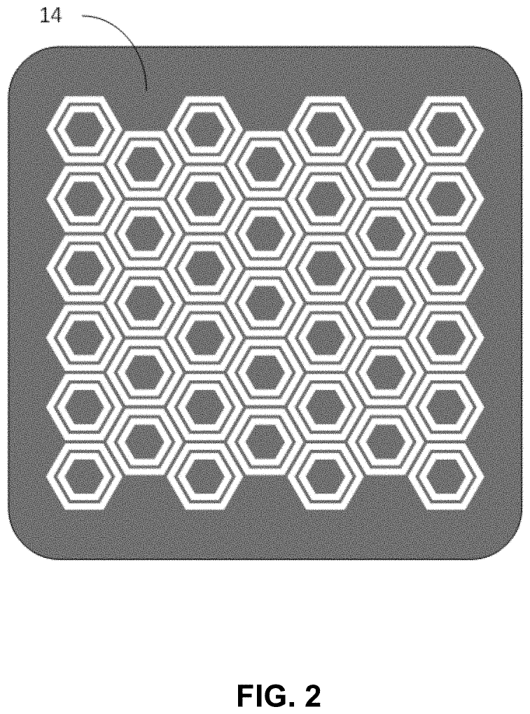

FIG. 2 illustrates a merged PiN Schottky (MPS) diode with hexagonal cell structure with P+ ring design in the region 14, which shows that a central hexagonal P+ island and a first hexagonal P+ outer ring are isolated from the adjacent P+ regions. Under a surge current condition, the PN junctions formed between the P+ regions 14 and the N-type drift region 15 will be turned on. Due to the bipolar effect, minority carriers are injected on both sides of the PN junction to form electron-hole plasmas. These plasmas are first generated under the PN junction. At the moment of the surge current occurs, it is difficult for these plasmas to rapidly spread to other part of the devices, same for the surge current and the heat generated inside the device. As a result, a localized heating phenomenon that causes the device to fail prematurely may be inevitable.

To resolve on the problem described above, a plasma spreading layer configured to connect the P+ regions is developed in the present invention. Once the surge current occurs, the plasma spreading layer can help rapidly diffusing the plasma to other drift regions, resulting in the surge current and the heat generated inside the device evenly and efficiently dispersed over the device to avoid localized heating.

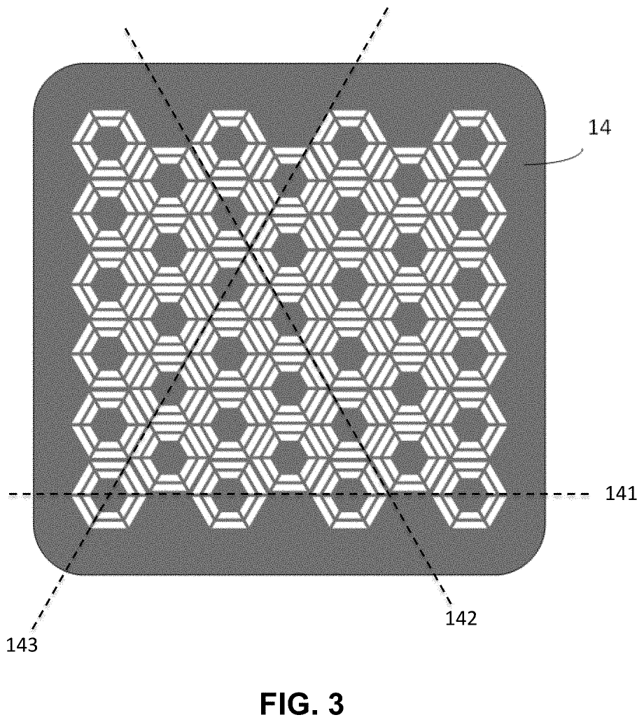

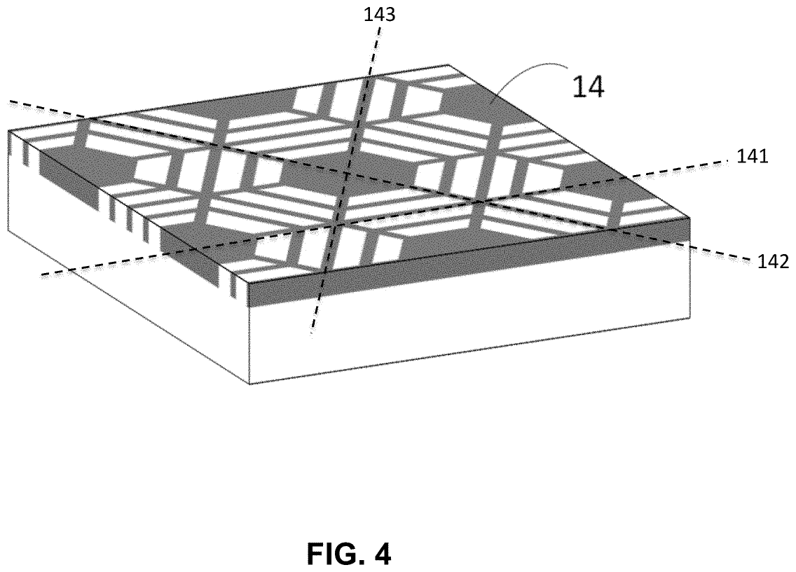

In one embodiment, a merged PiN Schottky (MPS) diode structure with hexagonal cells and P+ rings along with a plasma spreading layer is shown in FIGS. 3 and 4, which has three P+ type diagonal lines (141, 142, 143) for each cell, and forms 60 degrees with each other. It is noted that the plasma spreading layer design can connect all the P+ hexagons and outer P+ rings. During a surge current shock, the PN junction formed by the large P+ hexagon and N-type drift layer is first turned on, then the bipolar effect takes place and the electron-holes are created. With the help of the plasma spreading layer, the electron-hole plasma can be dispersed to the whole area of the device. As a result, the high surge current and dissipated energy can be evenly distributed within the device, effectively preventing the device damage caused by localized heating, and thus improving the surge current capability of the device.

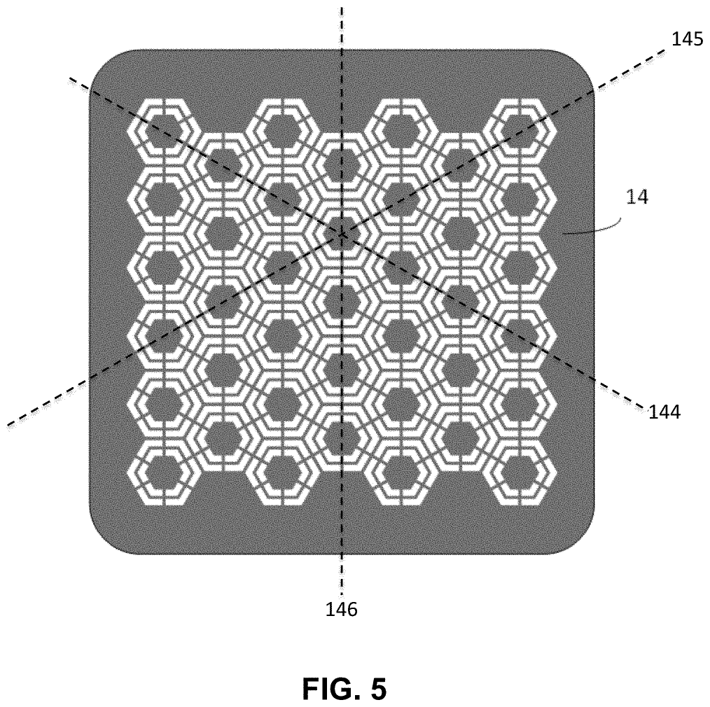

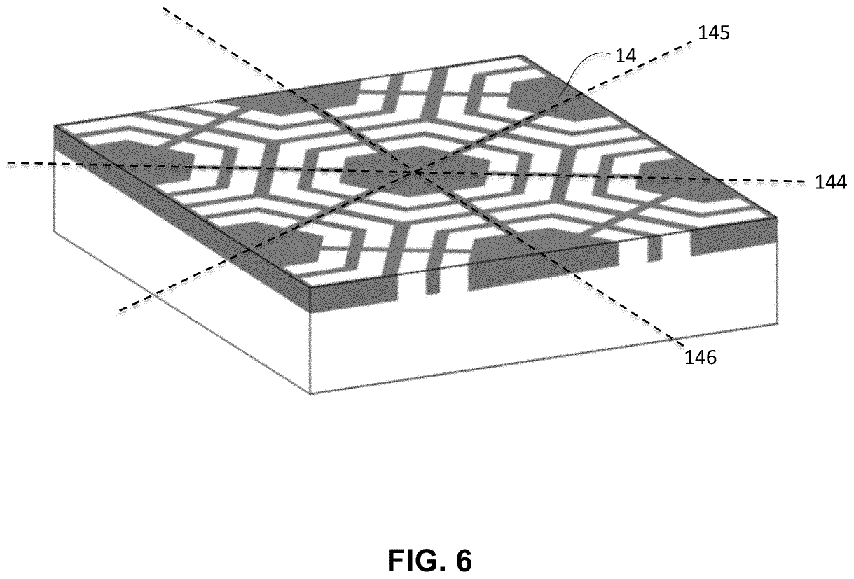

It is noted that there are various kinds of arrangements for the plasma spreading layer design. For example, rotating the plasma spreading layer by 30 degrees based on the design shown in FIG. 3, another layout design with 60-degree cross network shown in FIGS. 5 and 6 can be obtained, which also has three P+ type diagonal lines (144, 145, 146) for each cell, and forms 60 degrees with each other. Likewise, the plasma spreading layer design can connect all the P+ hexagons and outer P+ rings, and during a surge current shock, the PN junction formed by the large P+ hexagon and N-type drift layer is first turned on, then the bipolar effect takes place and the electron-holes are created. With the help of the plasma spreading layer, the electron-hole plasma can be dispersed to the whole area of the device. As a result, the high surge current and dissipated energy can be evenly distributed within the device, effectively preventing the device damage caused by localized heating, and thus improving the surge current capability of the device.

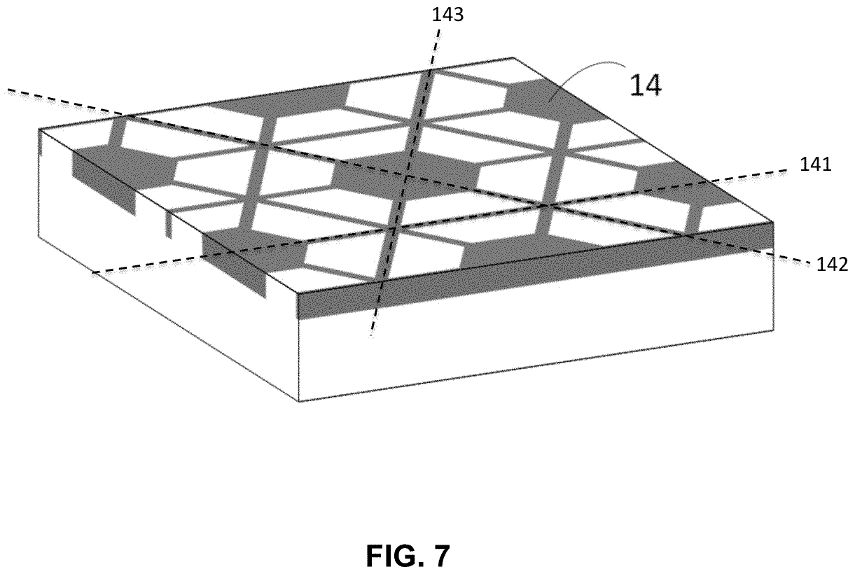

In another embodiment, as shown in FIG. 7, even if the number of the narrow P+ regions (i.e. the hexagonal rings) are reduced, as long as the device has the plasma spreading layer having three P+ type diagonal lines (141, 142, 143) for each cell, the current and the generated heat during the surge current shock can be uniformly diffused over the whole device area.

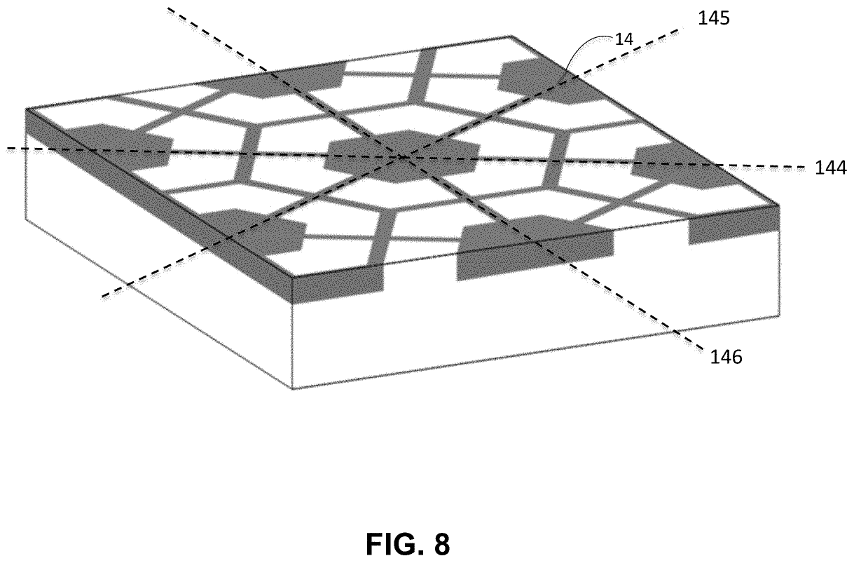

Likewise, rotating the plasma spreading layer by 30 degrees based on the design shown in FIG. 7 with reduced narrow P+ regions, another layout design with 60-degree cross network shown in FIG. 8 can be obtained, which also has three P+ type diagonal lines (144, 145, 146) for each cell, and forms 60 degrees with each other.

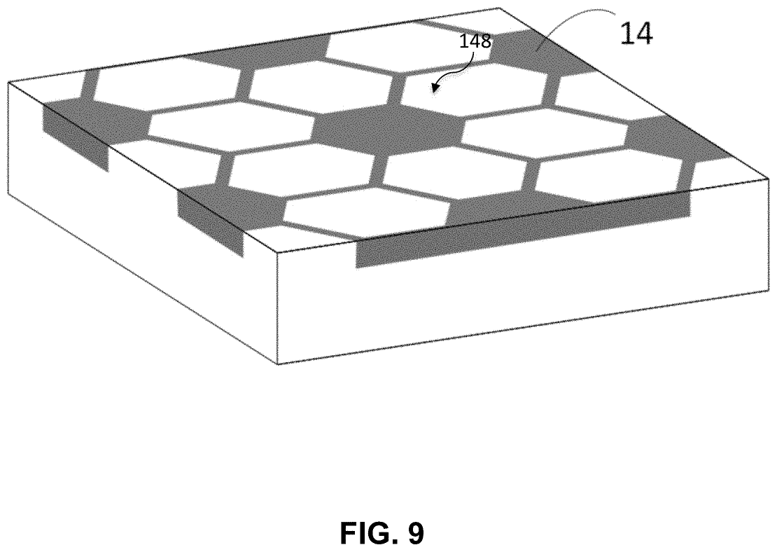

In addition to the cross-network structure formed by the straight lines as stated above, the plasma spreading layer can also be formed in other shapes. For example, FIG. 9 shows an interconnected hexagonal plasma spreading layer 148, which can also uniformly spread current and the generated heat to the whole device area, effectively preventing device damage caused by localized heating, improving the surge current capability.

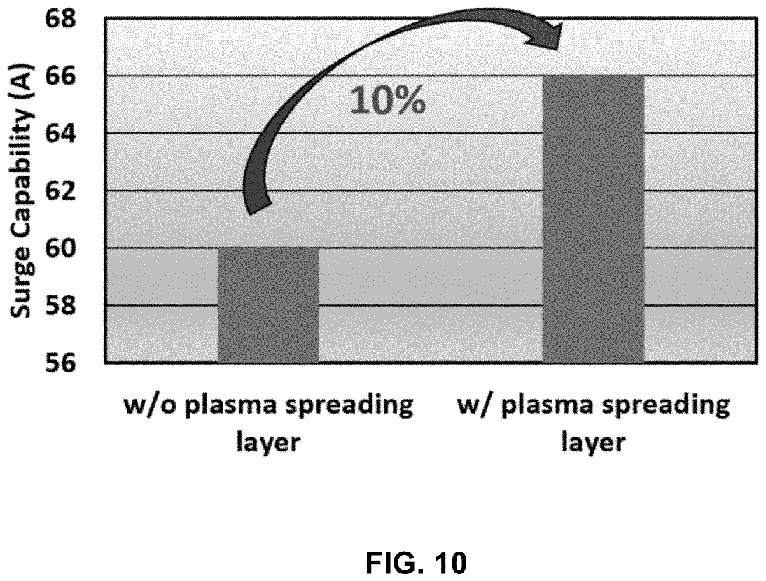

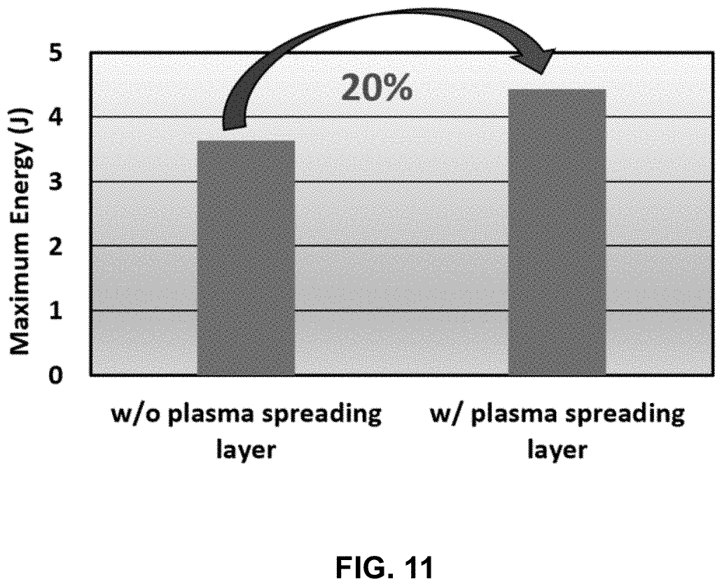

Through the experiment of the merged PiN junction Schottky (MPS) diode and corresponding surge current test in which a half-sinusoidal current pulse with pulse width of 10 ms is applied to the device, the surge current capability is summarized for two design groups: one is the MPS diode without a plasma spreading layer and the other is the MPS diode with a plasma spreading layer. The results are illustrated in FIG. 10. Also, the maximum energy the device can withstand before device failure is shown in FIG. 11.

As shown in FIGS. 10 and 11, the plasma spreading layer can increase the maximum energy (the device can withstand before device failure) of the merged PiN junction Schottky (MPS) diode by 20%, and subsequently improve the surge current capability by 10%, which confirms that the plasma spreading layer can facilitate the spread of plasma/current in the diode, and evenly diffuse the heat generated within the device, to effectively prevent device damage caused by localized heating, and improve the surge current capability.

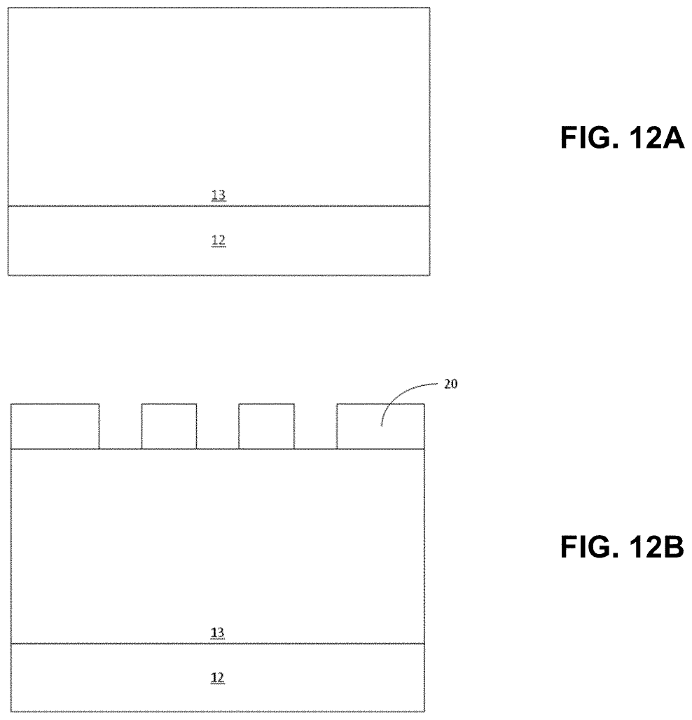

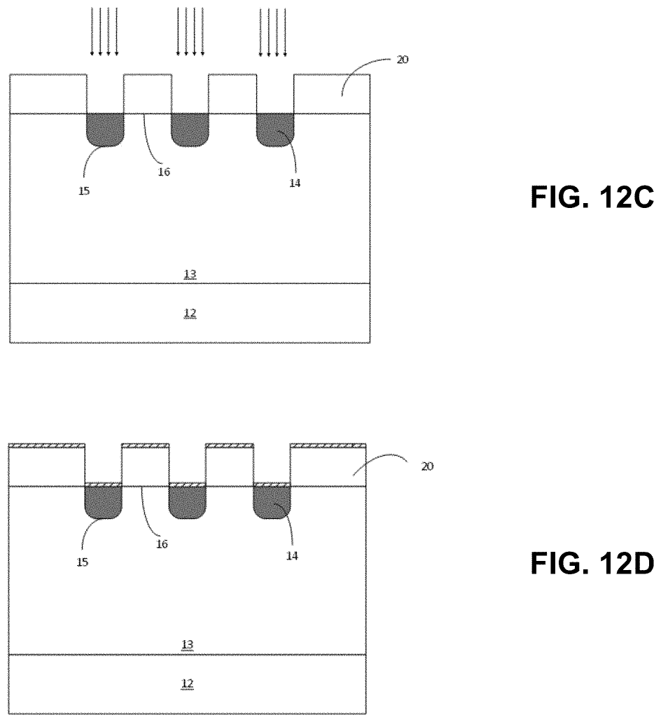

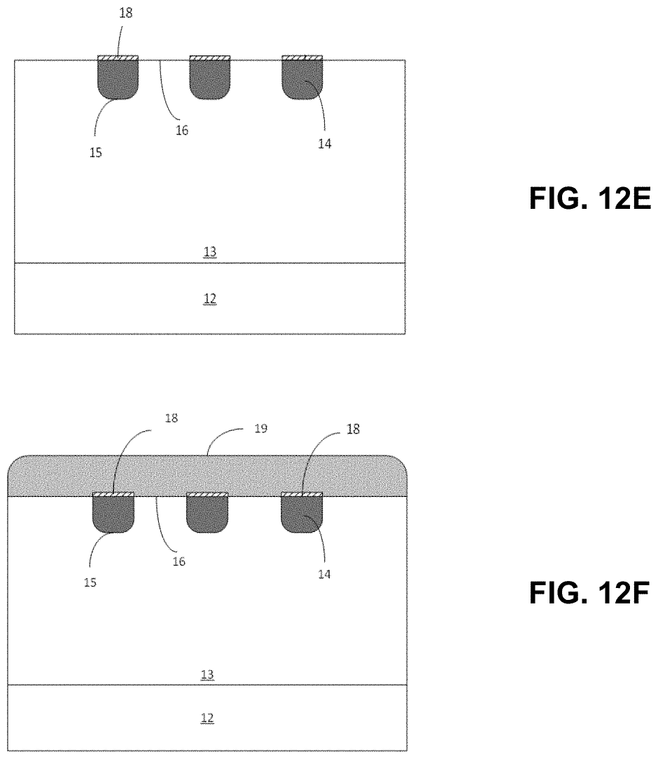

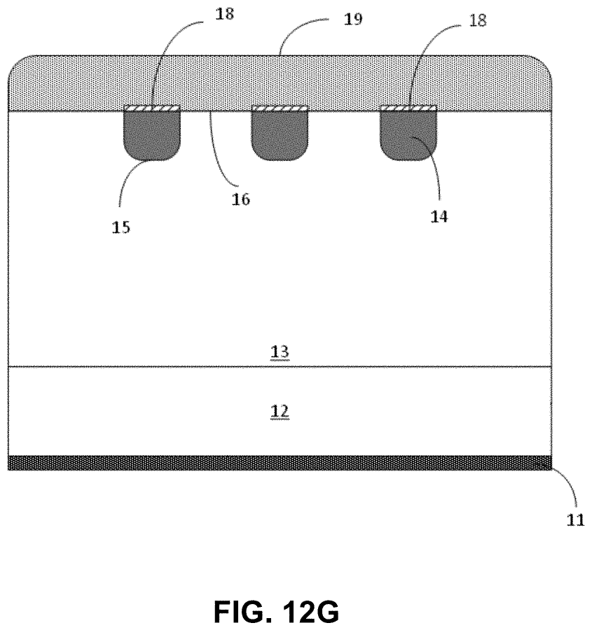

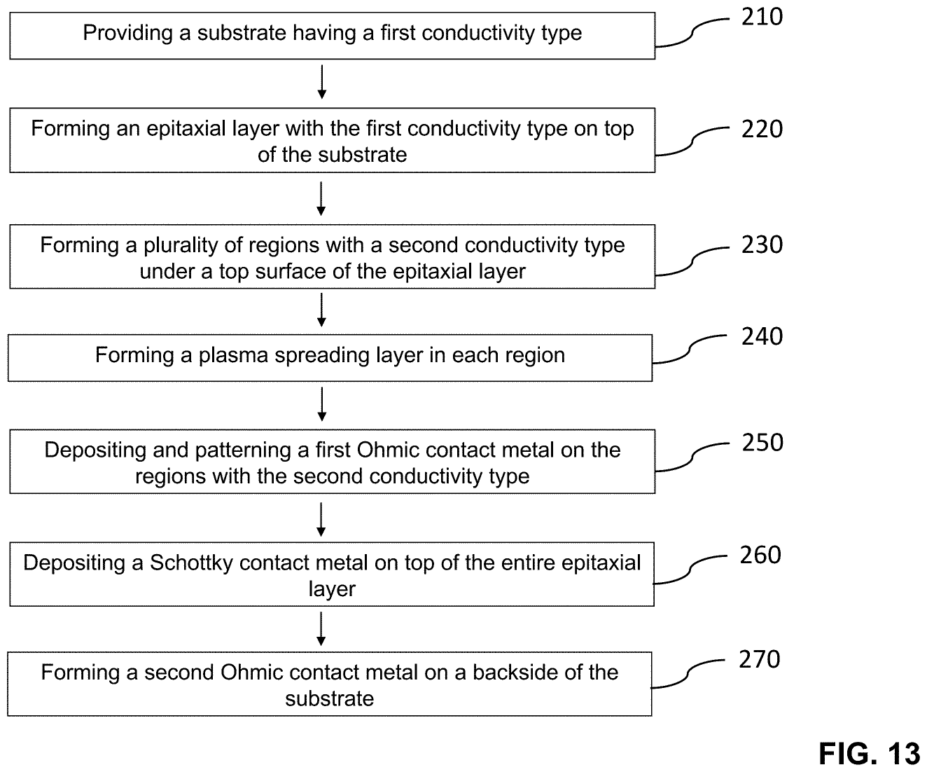

In another aspect, as shown in FIGS. 12A to 12G, and 13, a method for manufacturing a merged PiN Schottky (MPS) diode may include steps of providing a substrate having a first conductivity type 210; forming an epitaxial layer with the first conductivity type 220 on top of the substrate; forming a plurality of regions with a second conductivity type under a top surface of the epitaxial layer 230; forming a plasma spreading layer in each region 240; depositing and patterning an Ohmic contact metal on the regions with the second conductivity type 250; depositing a Schottky contact metal on top of the entire epitaxial layer 260; and forming an Ohmic contact metal on a backside of the substrate 270.

In one embodiment, the epitaxial layer is made of N-type silicon carbide. In another embodiment, the step of forming a plurality of regions with a second conductivity type under a top surface of the epitaxial layer 230 may include steps of depositing and patterning a mask layer 20 on the epitaxial layer 2301, implanting P-type dopant into the epitaxial layer 2302, and removing the mask layer 2303. It is noted that the dopant can be aluminum or boron.

In a further embodiment, the step of depositing and patterning an Ohmic contact metal on the regions 240 may include a step of annealing the Ohmic metal to enable the metal to be in direct contact with the epitaxial layer. In still a further embodiment, the step of depositing a Schottky contact metal on top of the entire epitaxial layer 250 may include a step of conducting a low temperature annealing of the Schottky contact metal.

Having described the invention by the description and illustrations above, it should be understood that these are exemplary of the invention and are not to be considered as limiting. Accordingly, the invention is not to be considered as limited by the foregoing description, but includes any equivalent.

What is claimed is:

1. A semiconductor device comprising:
a substrate having a first conductivity type;
an epitaxial layer having the first conductivity type deposited on one side of the substrate;
a plurality of regions having a second conductivity type formed under a top surface of the epitaxial layer;
a first Ohmic metal patterned and deposited on top of the regions with the second conductivity type;
a Schottky contact metal deposited on top of the entire epitaxial layer to form a Schottky junction; and
a second Ohmic metal deposited on a backside of the substrate,
wherein a plasma spreading layer is formed in each of the regions, and the plasma spreading layer is configured to diffuse plasma when a surge current occurs, so the surge current and heat generated inside the semiconductor device can be evenly and efficiently dispersed over the semiconductor device.

2. The semiconductor device of claim 1, wherein the first conductivity type is N-type and the second conductivity type is P-type; and each of the regions is a P+ region.

3. The semiconductor device of claim 1, wherein the semiconductor device is a merged PiN Schottky (MPS) diode.

4. The semiconductor device of claim 2, wherein a PN junction formed between each of the P+ regions and N-type drift regions is turned on when the surge current occurs, and plasmas are generated under the PN junction.

5. The semiconductor device of claim 2, wherein each P+ region has a plurality of hexagonal cells with one or more P+ rings and a plasma spreading layer that has three P+ type diagonal lines, which are 60 degrees with each other.

6. The semiconductor device of claim 2, wherein the plasma spreading layer can be formed in other shapes.

7. The semiconductor device of claim 4, wherein each P+ region has a plurality of hexagonal cells with one or more P+ rings and a plasma spreading layer that has three P+ type diagonal lines, which are 60 degrees with each other.

8. The semiconductor device of claim 4, wherein the plasma spreading layer can be formed in other shapes.

9. The semiconductor device of claim 3, wherein the plasma spreading layer can increase a maximum energy that the MPS diode can withstand before device failure by 20%.

10. The semiconductor device of claim 3, wherein the plasma spreading layer can improve the surge current capability of the MPS diode by 10%.

11. A method for manufacturing a merged PiN Schottky (MPS) diode comprising steps of:
providing a substrate having a first conductivity type;
forming an epitaxial layer with the first conductivity type on top of the substrate;
forming a plurality of regions with a second conductivity type under a top surface of the epitaxial layer;
forming a plasma spreading layer in each region;
depositing and patterning a first Ohmic contact metal on the regions with the second conductivity type;
depositing a Schottky contact metal on top of the entire epitaxial layer; and
forming a second Ohmic contact metal on a backside of the substrate,
wherein the plasma spreading layer is configured to diffuse plasma when a surge current occurs, so the surge current and heat generated inside the semiconductor device can be evenly and efficiently dispersed over the MPS diode.

12. The semiconductor device of claim 11, wherein the first conductivity type is N-type and the second conductivity type is P-type; and each of the regions is a P+ region.

13. The semiconductor device of claim 12, wherein a PN junction formed between each of the P+ regions and N-type drift regions is turned on when the surge current occurs, and plasmas are generated under the PN junction.

14. The semiconductor device of claim 12, wherein each P+ region has a plurality of hexagonal cells with one or more P+ rings and a plasma spreading layer that has three P+ type diagonal lines, which are 60 degrees with each other.

15. The semiconductor device of claim 11, wherein the plasma spreading layer can be formed in other shapes.

16. The semiconductor device of claim 13, wherein each P+ region has a plurality of hexagonal cells with one or more P+ rings and a plasma spreading layer that has three P+ type diagonal lines, which are 60 degrees with each other.

17. The semiconductor device of claim 13, wherein the plasma spreading layer can be formed in other shapes.
